(19) United States
(12) Patent Application Publication
(10) Pub. No.: US 2022/0367108 A1
(43) Pub. Date: Nov. 17, 2022

(54) INSULATING ELEMENT

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Satoshi AKUTSU, Yokohama (JP); Kazuyuki ITO, Kamakura (JP); Takuo KIKUCHI, Kamakura (JP); Nobuaki MAKINO, Fujisawa (JP); Tatsuya OHGURO, Yokohama (JP); Yoshihiko FUJI, Nakatsu (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 17/663,048

(22) Filed: May 12, 2022

(30) Foreign Application Priority Data
May 14, 2021 (JP) 2021-082450

(51) Int. Cl. H01F 27/32; H01F 27/24; H01F 27/28

(52) U.S. Cl. CPC H01F 27/323; H01F 27/24; H01F 27/2804; H01F 2027/2809

(57) ABSTRACT

An insulating element includes a first coil; a second coil; and an inter-layer insulating film located between the first coil and the second coil. The inter-layer insulating film includes a first layer, a second layer, and a third layer located between the first layer and the second layer. The first layer is located between the first coil and the third layer. The second layer is located between the second coil and the third layer. A bandgap of the third layer is narrower than a bandgap of the first layer and a bandgap of the second layer.

### CROSS-REFERENCE TO RELATED APPLICATION

This application is based upon and claims the benefit of priority from Japanese Patent Application No. 2021-082450, filed on May 14, 2021; the entire contents of which are incorporated herein by reference.

### FIELD

Embodiments described herein relate generally to an insulating element.

### BACKGROUND

A known insulating element includes a pair of coils, includes an inter-layer insulating film located between the pair of coils, and utilizes electromagnetic induction to transmit a signal between the pair of coils. There are cases where a high electric field is applied to the inter-layer insulating film between the pair of coils; and high reliability of the inter-layer insulating film is desirable.

### BRIEF DESCRIPTION OF THE DRAWINGS

FIG. 1 is a schematic cross-sectional view of an insulating element of an embodiment; and

FIG. 2A is an energy band diagram of an inter-layer insulating film of the embodiment when a voltage is applied between a first coil and a second coil, and FIG. 2B is an energy band diagram of an inter-layer insulating film of a comparative example when a voltage is applied between a first coil and a second coil.

### DETAILED DESCRIPTION

According to one embodiment, an insulating element includes a first coil; a second coil; and an inter-layer insulating film located between the first coil and the second coil. The inter-layer insulating film includes a first layer, a second layer, and a third layer located between the first layer and the second layer. The first layer is located between the first coil and the third layer. The second layer is located between the second coil and the third layer. A bandgap of the third layer is narrower than a bandgap of the first layer and a bandgap of the second layer.

Embodiments will now be described with reference to the drawings. The same components in the drawings are marked with the same reference numerals.

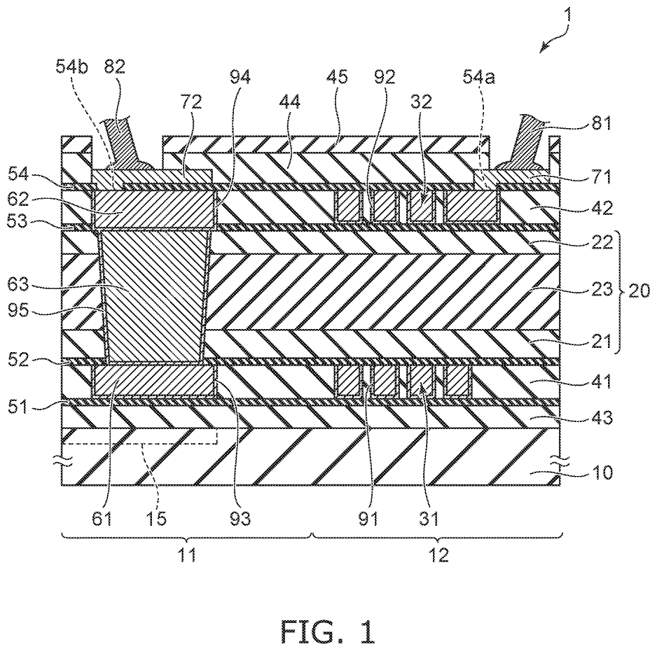

FIG. 1 is a schematic cross-sectional view of an insulating element 1 of an embodiment.

The insulating element 1 includes a first coil 31, a second coil 32, and an inter-layer insulating film 20. The inter-layer insulating film 20 is located between the first coil 31 and the second coil 32.

The inter-layer insulating film 20 includes a first layer 21, a second layer 22, and a third layer 23. The first layer 21 is located between the first coil 31 and the third layer 23. The second layer 22 is located between the second coil 32 and the third layer 23. The third layer 23 is located between the first layer 21 and the second layer 22.

The bandgap of the third layer 23 is narrower than the bandgap of the first layer 21 and the bandgap of the second layer 22. For example, the first layer 21 and the second layer 22 are silicon oxide layers. The silicon oxide layer is, for example, a SiO₂ layer. The third layer 23 is a silicon oxynitride layer. Or, the third layer 23 is a silicon nitride layer.

The thickness of the first layer 21 and the thickness of the second layer 22 are less than the thickness of the third layer 23. The thickness of the entire inter-layer insulating film 20 is, for example, about 10 μm. The thickness of the first layer 21 and the thickness of the second layer 22 are, for example, about 2 μm.

The insulating element 1 further includes a substrate 10, a first insulating layer 41, a second insulating layer 42, a third insulating layer 43, a fourth insulating layer 44, a first conductive layer 61, a second conductive layer 62, a third conductive layer 63, and a protective film 45.

The substrate 10 is, for example, a silicon substrate. The substrate 10 includes a first region 11 and a second region 12. The first region 11 of the substrate 10 includes a circuit 15. The circuit 15 includes a semiconductor integrated circuit. The circuit 15 includes, for example, a CMOS (Complementary Metal-Oxide-Semiconductor) circuit.

The third insulating layer 43 is located on the substrate 10; the first insulating layer 41 is located on the third insulating layer 43; the inter-layer insulating film 20 is located on the first insulating layer 41; and the second insulating layer 42 is located on the inter-layer insulating film 20.

The first insulating layer 41 is located between the substrate 10 and the inter-layer insulating film 20. The first insulating layer 41 is, for example, a silicon oxide layer.

The first conductive layer 61 is located in the first insulating layer 41 on the first region 11 of the substrate 10. For example, the first conductive layer 61 is electrically connected with the circuit 15 on the first region 11 by a not-illustrated conductive via, etc.

The first coil 31 is located in the first insulating layer 41 on the second region 12 of the substrate 10. For example, the first coil 31 and the first conductive layer 61 are made of the same material and are simultaneously formed. The first coil 31 and the first conductive layer 61 include, for example, mainly copper. For example, the first coil 31 is formed in a spiral shape in the first insulating layer 41. The first coil 31 is electrically connected with the first conductive layer 61 via a not-illustrated conductive layer located in the first insulating layer 41.

The second insulating layer 42 is located on the inter-layer insulating film 20. The inter-layer insulating film 20 is located between the first insulating layer 41 and the second insulating layer 42. The second insulating layer 42 is, for example, a silicon oxide layer.

The second conductive layer 62 is located in the second insulating layer 42 on the first region 11 of the substrate 10.

The second coil 32 is located in the second insulating layer 42 on the second region 12 of the substrate 10. For example, the second coil 32 and the second conductive layer 62 are made of the same material and are simultaneously formed. The second coil 32 and the second conductive layer 62 include, for example, mainly copper. For example, the second coil 32 is formed in a spiral shape in the second insulating layer 42. The second coil 32 is not connected with the second conductive layer 62 in the second insulating layer 42.

The third conductive layer 63 is located in the inter-layer insulating film 20 between the first conductive layer 61 and the second conductive layer 62 and electrically connects the first conductive layer 61 and the second conductive layer 62.

A barrier metal 91 is located between the first coil 31 and the first insulating layer 41. A barrier metal 93 is located between the first conductive layer 61 and the first insulating layer 41. A barrier metal 92 is located between the second coil 32 and the second insulating layer 42. A barrier metal 94 is located between the second conductive layer 62 and the second insulating layer 42. A barrier metal 95 is located between the third conductive layer 63 and the inter-layer insulating film 20.

The barrier metals 91 to 95 prevent the diffusion into the insulating materials of the metal atoms (e.g., copper atoms) included in the first coil 31, the second coil 32, the first conductive layer 61, the second conductive layer 62, and the third conductive layer 63. For example, Ta or TaN is used as the barrier metals 91 to 95.

The third insulating layer 43 is located between the substrate 10 and the first insulating layer 41. The third insulating layer 43 is, for example, a silicon oxide layer. A first insulating film 51 is located between the third insulating layer 43 and the first insulating layer 41. The first insulating film 51 is a film of a different material from the third and first insulating layers 43 and 41 and is, for example, a silicon nitride film.

A second insulating film 52 is located between the first insulating layer 41 and the first layer 21 of the inter-layer insulating film 20. The second insulating film 52 is a film of a different material from the first insulating layer 41 and the first layer 21 and is, for example, a silicon nitride film.

A third insulating film 53 is located between the second insulating layer 42 and the second layer 22 of the inter-layer insulating film 20. The third insulating film 53 is a film of a different material from the second layer 22 and the second insulating layer 42 and is, for example, a silicon nitride film.

The fourth insulating layer 44 is located on the second insulating layer 42. The fourth insulating layer 44 is, for example, a silicon oxide layer. A fourth insulating film 54 is located between the second insulating layer 42 and the fourth insulating layer 44. The fourth insulating film 54 is a film of a different material from the second and fourth insulating layers 42 and 44 and is, for example, a silicon carbonitride (SiCN) film.

The protective film 45 is located on the fourth insulating layer 44. The protective film 45 is an insulating film and is, for example, a silicon nitride film or an organic film such as polyimide.

A first pad 71 and a second pad 72 are located on the fourth insulating film 54. The first pad 71 and the second pad 72 are made of metal materials. The first pad 71 and the second pad 72 include, for example, mainly aluminum.

A first opening 54a that reaches the second coil 32 is formed in the fourth insulating film 54. A portion of the first pad 71 is formed in the first opening 54a and is connected with the second coil 32. The upper surface of the first pad 71 is exposed from under the fourth insulating layer 44 and the protective film 45. A first metal wire 81 is bonded to the upper surface of the first pad 71. The second coil 32 is electrically connected with the first metal wire 81 via the first pad 71.

A second opening 54b that reaches the second conductive layer 62 also is formed in the fourth insulating film 54. A portion of the second pad 72 is formed in the second opening 54b and is connected with the second conductive layer 62. The upper surface of the second pad 72 is exposed from under the fourth insulating layer 44 and the protective film 45. A second metal wire 82 is bonded to the upper surface of the second pad 72. The second conductive layer 62 is electrically connected with the second metal wire 82 via the second pad 72.

The first coil 31 is electrically connected with the second metal wire 82 via the first conductive layer 61, the third conductive layer 63, the second conductive layer 62, and the second pad 72.

An electrical signal from an external circuit or an external device is applied to the second coil 32 via the first metal wire 81 and the first pad 71. For example, a high frequency digital signal is applied to the second coil 32.

A magnetic field is generated by the electrical signal applied to the second coil 32; and the magnetic field generates an induced current in the first coil 31. Thereby, a signal is transmitted from the second coil 32 to the first coil 31. Conversely, a signal that is applied to the first coil 31 via the second metal wire 82, the second pad 72, the second conductive layer 62, the third conductive layer 63, and the first conductive layer 61 can be transmitted to the second coil 32 by electromagnetic induction. For example, a signal can be transmitted between the circuit 15, i.e., a semiconductor integrated circuit, and an external circuit (or external device) operating at a higher voltage than the circuit 15 while insulating the circuit 15 and the external circuit (or external device) with the inter-layer insulating film 20.

An electric field is applied to the inter-layer insulating film 20 when transmitting the signal between the first coil 31 and the second coil 32.

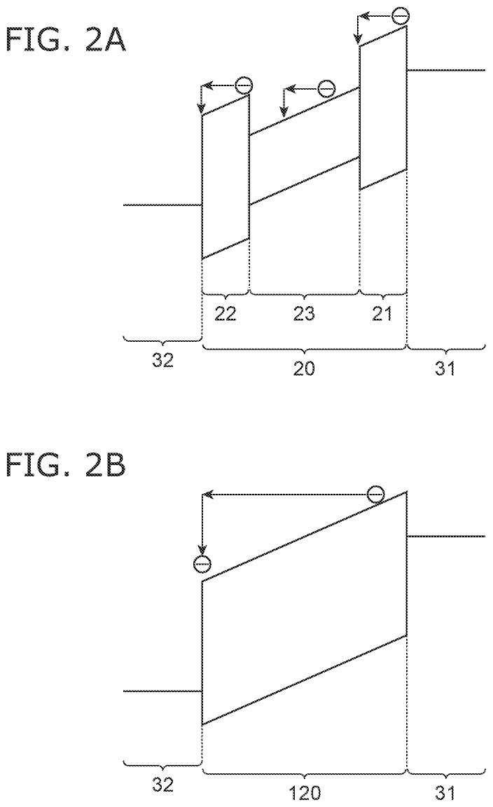

FIG. 2B is an energy band diagram of an inter-layer insulating film 120 of a comparative example when a voltage is applied between the first coil 31 and the second coil 32. The second coil 32 has a relatively high potential; and the first coil 31 has a relatively low potential.

In the comparative example, one silicon oxide (SiO₂) layer is used as the inter-layer insulating film 120. When a high electric field is applied to the inter-layer insulating film 120, the slope of the energy band increases; the electrons are quickly accelerated; and there is a risk that avalanche breakdown may occur.

Conversely, FIG. 2A is an energy band diagram of the inter-layer insulating film 20 of the embodiment when the voltage is applied between the first coil 31 and the second coil 32. The second coil 32 has a relatively high potential; and the first coil 31 has a relatively low potential.

In the inter-layer insulating film 20 according to the embodiment, the third layer 23 that has a narrower bandgap than the first and second layers 21 and 22 is located between the first layer 21 and the second layer 22. Therefore, the number of collisions of the electrons with the atoms included in the inter-layer insulating film 20 can be increased compared to the comparative example described above. In other words, the frequency that the electrons collide with the atoms of the inter-layer insulating film 20 without being accelerated to a high energy is increased. The avalanche breakdown of the inter-layer insulating film 20 can be suppressed thereby, and the reliability of the inter-layer insulating film 20 can be increased. As a result, the breakdown of the insulating element 1 can be suppressed.

Even when the second coil 32 has a relatively low potential, and the first coil 31 has a relatively high potential, by the third layer 23 having a narrower bandgap than the first and second layers 21 and 22 and by providing the third layer 23 between the first layer 21 and the second layer 22, the number of collisions of the electrons can be increased compared to the comparative example; and the avalanche breakdown in the inter-layer insulating film 20 can be suppressed.

According to the embodiment, for example, silicon oxide layers are used as the first and second layers 21 and 22; and a silicon oxynitride layer is used as the third layer 23. Compared to silicon oxide, there is a tendency for the breakdown of silicon oxynitride to be dependent on the pass-through charge amount and independent of the electric field. The pass-through charge amount is the charge amount that passes through the insulating film until the insulating film reaches breakdown.

Accordingly, it is sufficient for the thickness of the first layer 21 and the thickness of the second layer 22 to be sufficient to suppress injection of electrons into the third layer 23. The first layer 21 and the second layer 22 do not have to be thicker than necessary. Cracks that occur due to a film stress increase when increasing the thicknesses of the first and second layers 21 and 22 can be suppressed thereby.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. An insulating element, comprising:
a first coil;
a second coil; and
an inter-layer insulating film located between the first coil and the second coil,
the inter-layer insulating film including a first layer, a second layer, and a third layer located between the first layer and the second layer,
the first layer being located between the first coil and the third layer,
the second layer being located between the second coil and the third layer,
a bandgap of the third layer being narrower than a bandgap of the first layer and a bandgap of the second layer.

2. The element according to claim 1, wherein
the first layer and the second layer are silicon oxide layers, and
the third layer is a silicon oxynitride layer.

3. The element according to claim 1, wherein
the first layer and the second layer are silicon oxide layers, and
the third layer is a silicon nitride layer.

4. The element according to claim 1, wherein
a thickness of the first layer and a thickness of the second layer are less than a thickness of the third layer.

5. The element according to claim 1, further comprising:
a substrate including first and second regions;
a first insulating layer located between the substrate and the inter-layer insulating film;
a first conductive layer located in the first insulating layer on the first region;
a second insulating layer located on the inter-layer insulating film;
a second conductive layer located in the second insulating layer on the first region; and
a third conductive layer located in the inter-layer insulating film,
the third conductive layer connecting the first conductive layer and the second conductive layer,
the first coil being located in the first insulating layer on the second region,
the first coil being connected with the first conductive layer,
the second coil being located in the second insulating layer on the second region,
the second coil not being connected with the second conductive layer.

6. The element according to claim 5, wherein
the first region of the substrate includes a circuit connected with the first conductive layer.

7. The element according to claim 6, wherein
the circuit includes a CMOS (Complementary Metal-Oxide-Semiconductor) circuit.

8. The element according to claim 5, wherein
the first coil is made of a same material as the first conductive layer.

9. The element according to claim 8, wherein
the first coil and the first conductive layer include mainly copper.

10. The element according to claim 5, wherein
the second coil is made of a same material as the second conductive layer.

11. The element according to claim 10, wherein
the second coil and the second conductive layer include mainly copper.
